(19) United States
(12) Patent Application Publication
(10) Pub. No.: US 2025/0344362 A1
(43) Pub. Date: Nov. 6, 2025

(54) ELECTROMAGNETIC WAVE SHIELDING SHEET AND MANUFACTURING METHOD THEREOF

(71) Applicant: VAULT CREATION CO., LTD., Seoul (KR)

(72) Inventor: Sang Jun CHOI, Seoul (KR)

(73) Assignee: VAULT CREATION CO., LTD., Seoul (KR)

(21) Appl. No.: 18/294,954

(22) PCT Filed: Aug. 1, 2022
(86) PCT No.: PCT/KR2022/011303

§ 371 Date: Mar. 18, 2025

(30) Foreign Application Priority Data
Aug. 3, 2021 (KR) 10-2021-0102012

(51) Int. Cl. H05K 9/00

(52) U.S. Cl. CPC H05K 9/0086

(57) ABSTRACT

The present invention relates to an electromagnetic wave shielding sheet satisfying two conditions of maintaining transparency (visibility) and improving electromagnetic wave shielding performance and a manufacturing method thereof. One feature of the present invention provides a transparent sheet through which light can be transmitted, and an electromagnetic wave shielding sheet including a conductive metal pattern defined by lines on the transparent sheet. The conductive metal pattern may include a first row, a second row, . . . , and an Nth row formed by arranging figures of the same shape in a row to partially overlap each other. In addition, the first row, the second row, . . . , and the Nth row may be arranged in columns to partially overlap each other.

### TECHNICAL FIELD

The present invention relates to shielding of electromagnetic waves or electromagnetic interference (EMI), and more specifically, to an electromagnetic wave shielding sheet with a conductive metal pattern formed on a transparent material sheet and a manufacturing method thereof.

### BACKGROUND ART

There are films or sheets that can shield electromagnetic waves or electromagnetic interference (EMI) generated from conventional cathode ray tubes, recent flat-screen monitors, and various industrial, civilian, and military devices and components.

In particular, electromagnetic wave shielding sheets used in monitor screens or optical products should effectively absorb electromagnetic waves such as radio waves and microwaves or EMI while maintaining transparency to visible light or infrared light.

However, conventional EMI shielding technology uses metal materials in mesh or grid patterns to shield EMI, and these patterns are opaque, resulting in a problem of low light transmittance and a light scattering. To solve this problem, a film has been developed that maintains transparency and provides an electromagnetic wave shielding function by forming specific patterns of metal on a transparent material.

Examples of conductor patterns applied to the conventional EMI shielding film include a randomly distributed elliptical pattern as shown in FIG. 1A or a regular pattern as shown in FIG. 1B.

### DISCLOSURE

### Technical Problem

The present invention is directed to providing an electromagnetic wave shielding sheet and a manufacturing method thereof, which maintains transparency (visibility) and enhances electromagnetic wave shielding performance in an electromagnetic wave shielding sheet.

### Technical Solution

One aspect of the present invention provides an electromagnetic wave shielding sheet including a transparent sheet through which light passes, and a conductive metal pattern defined by a line on the transparent sheet.

Another aspect of the present invention provides a method of manufacturing an electromagnetic wave shielding sheet, which includes depositing a conductive metal material on a transparent sheet material, defining a pattern on the deposited conductive metal material, and forming the defined conductive metal pattern.

The conductive metal pattern may include a first row, a second row, . . . , and an N^{th} row in which identically-shaped figures are disposed to partially overlap in rows. The first row, the second row, . . . , and the N^{th} row may be disposed to partially overlap in columns.

The configuration and operation of the present invention will become more apparent from embodiments described in detail below with reference to the drawings.

### Advantageous Effects

In accordance with the present invention, by forming a conductive metal pattern with a unique pattern on a transparent glass material, the performance of shielding electromagnetic waves such as electromagnetic interference (EMI) is uniform over the entire area of the sheet so that electromagnetic wave reflection and absorption performance can be improved and the transmittance of visible light (or infrared light) cannot be impaired. In addition, by applying an anti-reflective coating layer, light emitted to an electromagnetic wave shielding sheet is not reflected from a surface and is completely incident on and transmitted inside the sheet so that visibility can be further improved.

### DESCRIPTION OF DRAWINGS

FIGS. 1A and 1B are exemplary diagrams illustrating a conductor pattern of a conventional electromagnetic wave shielding sheet.

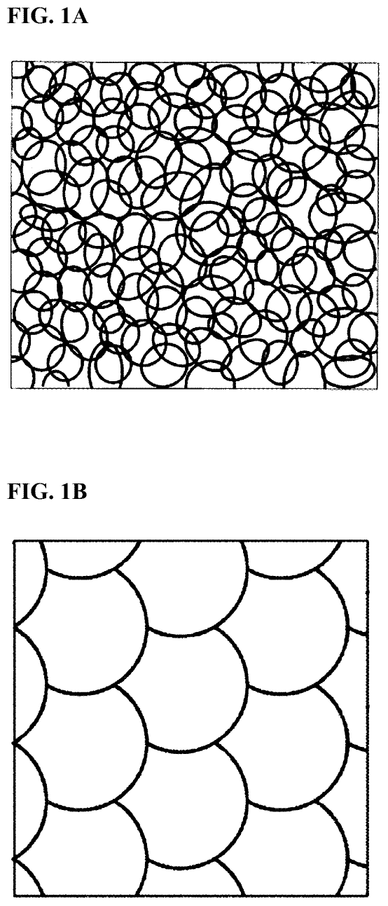

FIGS. 2A and 2B are diagrams illustrating an electromagnetic wave shielding sheet according to one embodiment of the present invention.

FIG. 3 is a diagram illustrating a size of a circular shape (30) forming a conductive metal pattern (20) according to the above embodiment.

FIGS. 4A and 4B are diagrams illustrating an electromagnetic wave shielding sheet according to another embodiment of the present invention.

FIG. 5 is a diagram illustrating a size of a hexagonal shape (50) forming a conductive metal pattern (40) according to the above embodiment.

FIG. 6 shows a process flowchart illustrating a method of manufacturing an electromagnetic wave shielding sheet according to the present invention and a cross-sectional view illustrating an intermediate product.

### MODES OF THE INVENTION

Hereinafter, exemplary embodiments of the present invention will be described in detail with reference to the accompanying drawings. Terms used herein are for the purpose of describing the embodiments of the present invention and are not intended to limit the present invention. In the present specification, the singular forms include the plural forms unless the context clearly dictates otherwise. The term “comprise” or “comprising” used herein does not preclude the presence or addition of one or more other elements, steps, operations, and/or devices other than the stated elements, steps, operations, and/or devices.

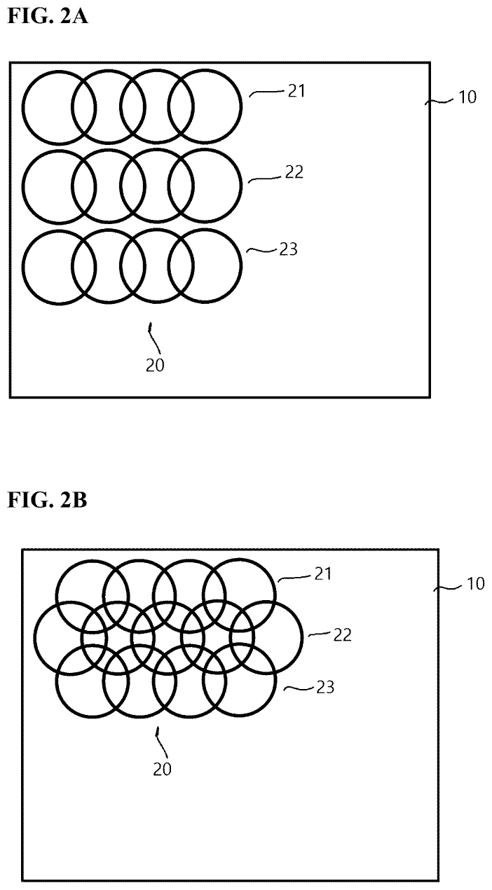

FIGS. 2A and 2B are diagrams illustrating an electromagnetic wave shielding sheet according to one embodiment of the present invention.

A conductive metal pattern 20 with a uniform micrometer-scale thickness is formed on a sheet 10 made of transparent glass through which light passes.

The conductive metal pattern 20 is designed to achieve the purpose of maximizing electromagnetic wave shielding performance while maintaining visibility through the transparency of transparent glass.

In the example of FIG. 2A, the conductive metal pattern 20 includes a first row 21, a second row 22, . . . , an N^{th} row of a plurality of identically shaped figures (here, circular shapes) disposed in rows, which partially overlap each other.

The conductive metal pattern 20 according to the example of FIG. 2B is formed with a higher density by partially overlapping the circles of each row in columns.

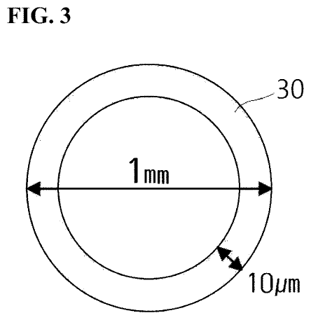

FIG. 3 is a diagram illustrating a size of a basic circular shape 30 forming the conductive metal pattern 20 according to the embodiment. A diameter (outer diameter) ranges from about 0.1 mm to 3 mm, and a thickness of a line defining the circle is about 10 μm or less. However, in the example of FIG. 3, a diameter of 1 mm is exemplified as one example of the diameter range.

Here, the circular shape includes not only a complete circle but also an ellipse and includes other round curved shapes.

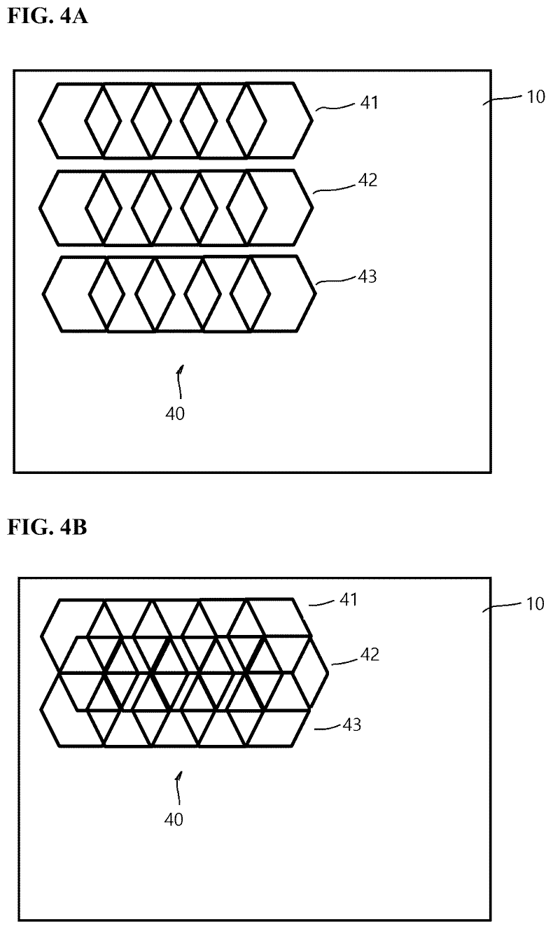

FIGS. 4A and 4B are diagrams illustrating an electromagnetic wave shielding sheet according to another embodiment of the present invention.

As in the previous embodiment, a conductive metal pattern 40 with a uniform micrometer-scale thickness is formed on a sheet 10 made of transparent glass through which light passes. The conductive metal pattern 40 is designed to achieve the purpose of maximizing electromagnetic wave shielding performance while maintaining visibility through the transparency of transparent glass.

In the example of FIG. 4A, the conductive metal pattern 40 includes a first row 41, a second row 42, a third row 43 . . . , an N^{th} row of a plurality of identical hexagonal shapes disposed in rows, which partially overlap each other.

In addition, the conductive metal pattern 40 according to the example of FIG. 4B is formed with a higher density by partially overlapping the hexagonal shapes of each row in columns.

By using the conductive metal patterns 20 and 40 with the same pattern as shown in FIGS. 2A and 2B and FIGS. 4A and 4B, electromagnetic interference (EMI) shielding performance is uniform over the entire area of the sheet, and thus EMI reflection/absorption (shielding) performance is improved and the transmittance of visible light (or infrared light) is not impaired.

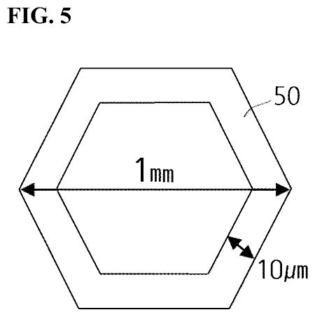

FIG. 5 is a diagram illustrating a size of a basic hexagonal shape 50 forming the conductive metal pattern 40 according to the embodiment. A size (length) between vertices ranges from about 0.1 mm to 3 mm, and a thickness of a line defining the hexagonal shape is about 10 μm or less. However, in the example of FIG. 5 a size of 1 mm is exemplified as one example of the size range.

Here, the hexagonal shape is used as a basic shape of the conductive metal pattern 40, but the present invention is not limited thereto. For example, polygonal shapes such as a triangular shape, a quadrangular shape, and a pentagonal shape may also be used.

Meanwhile, in the above two embodiments, after the conductive metal patterns 20 and 40 are formed on the transparent sheet 10, the entire surface may be additionally coated with an anti-reflective layer. The electromagnetic wave shielding sheet according to the present invention is basically used in devices or parts requiring optical transmission. In order to ensure that emitted light is not reflected from a surface of the electromagnetic wave shielding sheet but is completely incident on and transmitted inside the sheet, the surface is coated with the anti-reflective layer.

A thickness of the conductive metal patterns 20 and 40 formed on the transparent sheet 10 ranges from about 100 nm to 10 μm.

The conductive metal patterns 20 and 40 may be formed through photolithography and an etching process. This manufacturing method will be described below.

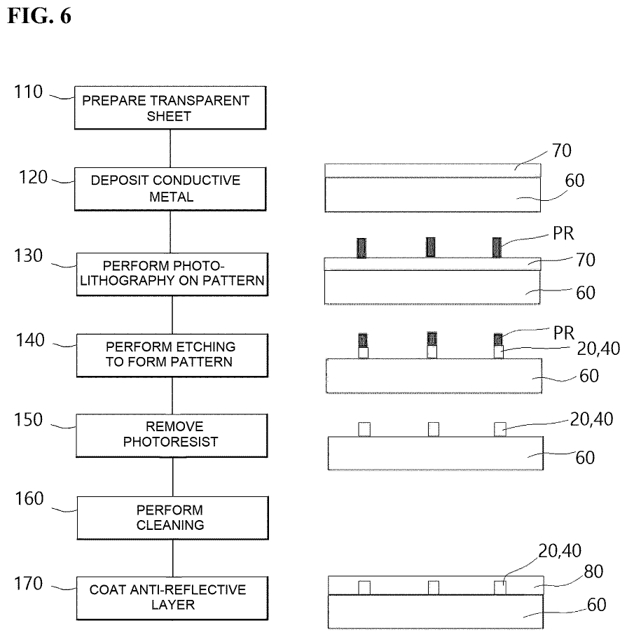

FIG. 6 is a diagram for describing a method of manufacturing an electromagnetic wave shielding sheet according to the present invention, a left side shows a process sequence, and a right side shows a cross-sectional view of an intermediate product obtained in the process.

First, a transparent sheet material 60 is prepared (110). Here, the transparent sheet may be made of glass, but the present invention is not limited thereto.

A conductive metal material 70 is deposited on the transparent sheet material 60 (120). The conductive metal material 70 may be deposited using a highly conductive material, for example, aluminum, gold, copper, or nickel. A deposition thickness of the metal material 70 may be about 100 nm or more and 10 μm or less.

The above-described conductive metal pattern 20 or 40 is defined through a photoresist PR using photolithography (130).

Etching is performed to form the conductive metal pattern 20 or 40 by leaving only a portion defined by the photoresist PR (140). Various etching methods may be used, but in order to increase the resolution of the pattern, isotropic etching or dry etching may be used. A cross-sectional view of an intermediate product after the etching is shown on the right side of FIG. 6.

After the conductive metal pattern 20 or 40 is formed by etching, the remaining photoresist PR is removed (150).

The intermediate product from which the photoresist PR is removed and in which the transparent sheet 60 and the conductive metal pattern 20 or 40 remain is cleaned to remove impurities and residues (160).

Finally, a surface on which the conductive metal pattern 20 or 40 is formed is finished by coating with an anti-reflective layer 80 (170). As described above, the reason for coating the anti-reflective layer 80 is to ensure that light emitted to the electromagnetic wave shielding sheet is not reflected from the surface and is completely incident on and transmitted inside the sheet.

The embodiments implementing the spirit of the present invention have been described in detail. However, the technical scope of the present invention is not limited to the above-described embodiments and the accompanying drawings and is determined by reasonable interpretation of the appended claims.

1. An electromagnetic wave shielding sheet comprising:
a transparent sheet through which light passes; and
a conductive metal pattern defined by a line on the transparent sheet, wherein the conductive metal pattern includes a first row, a second row, . . . , and an N^{th} row in which identically-shaped figures are disposed to partially overlap in rows.

2. The electromagnetic wave shielding sheet of claim 1, wherein the first row, the second row, . . . , and the N^{th} row are disposed to partially overlap in columns.

3. The electromagnetic wave shielding sheet of claim 1, wherein the transparent sheet is made of glass.

4. The electromagnetic wave shielding sheet of claim 1, wherein a shape of the conductive metal pattern is one of a complete circular shape, an elliptical shape, and a rounded curve shape.

5. The electromagnetic wave shielding sheet of claim 1, wherein a shape of the conductive metal pattern is one of a triangular shape, a quadrangular shape, a pentagonal shape, a hexagonal shape, and other polygonal shapes.

6. The electromagnetic wave shielding sheet of claim 1, wherein a size of the conductive metal pattern ranges from 0.1 mm to 3 mm.

7. The electromagnetic wave shielding sheet of claim 1, wherein a thickness of the line defining the conductive metal pattern is 10 μm or less.

8. The electromagnetic wave shielding sheet of claim 1, wherein a thickness of the conductive metal pattern ranges from 100 nm to 10 μm.

9. The electromagnetic wave shielding sheet of claim 1, further comprising an anti-reflective layer coated on at least a surface of the transparent sheet on which the conductive metal pattern is formed.

10. A method of manufacturing an electromagnetic wave shielding sheet, comprising:
depositing a conductive metal material on a transparent sheet material;
defining a pattern on the deposited conductive metal material; and
forming the defined conductive metal pattern,
wherein the conductive metal pattern includes a first row, a second row, . . . , and an N^{th} row in which identically-shaped figures are disposed to partially overlap in rows.

11. The method of claim 10, wherein the first row, the second row, . . . , and the N^{th} row are disposed to partially overlap in columns.

12. The method of claim 10, wherein a shape of the conductive metal pattern is one of a complete circular shape, an elliptical shape, and a rounded curve shape.

13. The method of claim 10, wherein a shape of the conductive metal pattern is one of a triangular shape, a quadrangular shape, a pentagonal shape, a hexagonal shape, and other polygonal shapes.

14. The method of claim 10, further comprising depositing an anti-reflective layer on at least a surface on which the conductive metal pattern is formed.
